(19) United States
(12) Patent Application Publication
(10) Pub. No.: US 2010/0048022 A1
(43) Pub. Date: Feb. 25, 2010

(54) SEMICONDUCTOR MANUFACTURING APPARATUS AND METHOD OF MANUFACTURING SEMICONDUCTOR DEVICE

(75) Inventor: Hiroshi KUBOTA, Yokkaichi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Minato-ku (JP)

(21) Appl. No.: 12/490,681

(22) Filed: Jun. 24, 2009

(30) Foreign Application Priority Data
Aug. 25, 2008 (JP) 2008-215249

(51) Int. Cl. H01L 21/465; C23F 1/02; C23C 16/50

(52) U.S. Cl. 438/694; 156/345.34; 216/67; 118/723 R; 257/E21.485

(57) ABSTRACT

A semiconductor manufacturing apparatus that forms a carbon film on a wafer by plasma enhanced chemical vapor deposition includes a body having a top opening; a stage provided within the body for placement of the wafer; a showerhead that encloses the top opening and that introduces a deposition gas or an etch gas; and a gas delivery system including a central gas inlet that introduces gas toward a central portion of the wafer from a central portion of the showerhead, and a peripheral gas inlet that introduces gas toward a bevel of the wafer from an outer peripheral portion of the showerhead, wherein the gas delivery system, after activating the etch gas outside the body, delivers the activated etch gas toward the bevel of the wafer to selectively remove a portion of the carbon film formed on the bevel of the wafer.

### CROSS-REFERENCE TO RELATED APPLICATIONS

This application is based upon and claims the benefit of priority from the prior Japanese Patent Application No. 2008-215249, filed on, Aug. 25, 2008 the entire contents of which are incorporated herein by reference.

### FIELD

The present disclosure relates to a semiconductor manufacturing apparatus and method of manufacturing a semiconductor device.

### BACKGROUND

Sidewall processing is known as a typical technology in forming smaller line and space patterns. Sidewall processing involves forming a core material, forming a spacer film comprising an amorphous silicon (a-Si) film, for example to perform a series of required processes, removing the core material, and processing the underlying features using the remaining spacer film as a mask. Core materials generally used in the above described sidewall processing are films such as TEOS film and SiN film formed by LPCVD (Low Pressure Chemical Vapor Deposition). Recent development has found carbon CVD film as a possible alternative to the conventional approach. Carbon CVD film is formed by PECVD (Plasma Enhance Chemical Vapor Deposition) and can be removed by dry etching such as O₂ ashing.

Some of the disadvantages encountered in employing a core material comprising carbon CVD film were contamination within the fabrication equipment caused by delaminated or broken away fragments of spacer film overlying the carbon CVD film formed on the wafer bevel (outer peripheral edge) and wafer contamination by dust transferred onto the wafer which was produced by fragments of carbon CVD film delaminating from the wafer bevel when removing the core material by O₂ ashing. It is thus, desirable not to allow any carbon CVD film to remain on the wafer bevel after formation of the carbon CVD film.

One possible solution to the above described problems may be dry etching the carbon CVD film by O₂ ashing, or the like, in the load lock chamber after formation of the carbon CVD film. The problem with such approach is contamination by dust blown up by large pressure variance caused by transfer of wafer in and out of the load lock chamber and significantly reduced throughput. Another problem is increased complexity of the fabrication equipment since exhaust from the load lock chamber need to be rendered dust-free by devices such as a filtering device.

One example of a dedicated etching equipment for etching the wafer bevel is disclosed in 2006-120875 A.

### SUMMARY

In one aspect of the present invention, there is provided a semiconductor manufacturing apparatus that forms a carbon film on a wafer by plasma enhanced chemical vapor deposition including a body having a top opening; a stage provided within the body for placement of the wafer; a showerhead that encloses the top opening and that introduces a deposition gas or an etch gas; and a gas delivery system including a central gas inlet that introduces gas toward a central portion of the wafer from a central portion of the showerhead, and a peripheral gas inlet that introduces gas toward a bevel of the wafer from an outer peripheral portion of the showerhead, wherein the gas delivery system, after activating the etch gas outside the body, delivers the activated etch gas toward the bevel of the wafer to selectively remove a portion of the carbon film formed on the bevel of the wafer.

In another aspect of the present invention, there is provided a method of manufacturing a semiconductor device in which a carbon film formation with plasma enhanced chemical vapor deposition is performed including forming the carbon film on a wafer by introducing a deposition gas from a central gas inlet positioned at a central portion of a showerhead and a peripheral gas inlet positioned at a peripheral portion of the showerhead, the showerhead enclosing an upper opening of a body of a plasma enhanced chemical vapor deposition apparatus, and etching away the carbon film formed on a bevel of the wafer by delivering a first etch gas activated outside the body toward the bevel of the wafer from the peripheral gas inlet.

### BRIEF DESCRIPTION OF THE DRAWINGS

FIG. 1 is a vertical cross sectional view of a PECVD apparatus according to one exemplary embodiment of the present invention;

FIG. 2 is a perspective view of an exhaust element;

FIG. 3 is a descriptive view of a gas delivery system;

FIGS. 4A to 4F are cross sectional views describing film formation and etching performed at an outer peripheral edge of a wafer;

FIGS. 5A to 5F are comparative examples corresponding to FIGS. 4A to 4F;

FIG. 6 is a chart indicating an ON/OFF state of a high-frequency power supply, an ON/OFF state of a reaction chamber, and an OPEN/CLOSE status of each valve;

FIG. 7 corresponds to FIG. 3 and depicts a second exemplary embodiment; and

FIG. 8 corresponds to FIG. 6.

### DETAILED DESCRIPTION

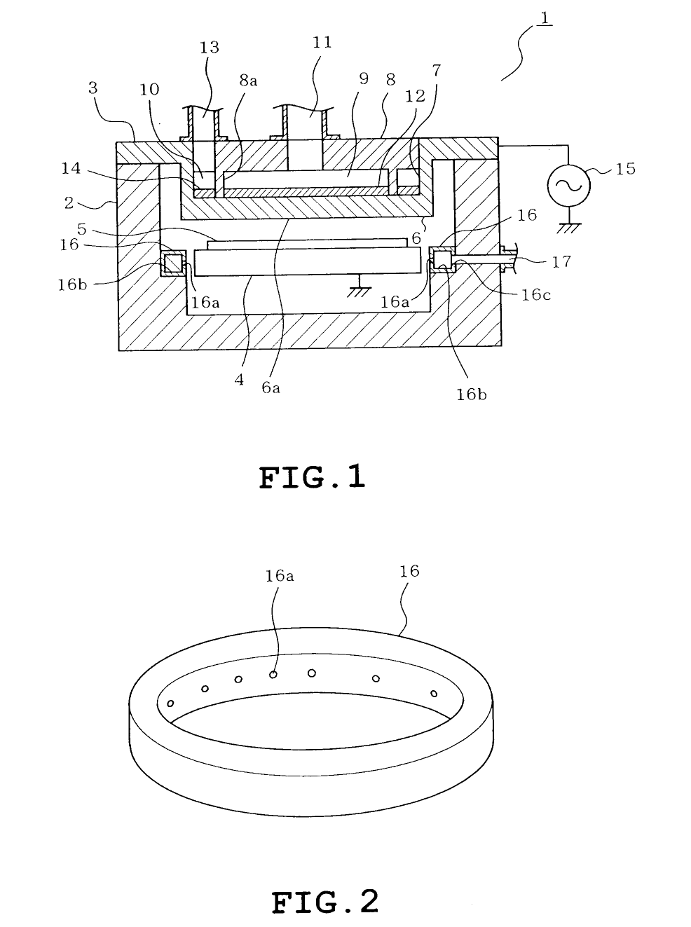

A description will be given hereinafter on a first exemplary embodiment of the present invention with reference to FIGS. 1 to 6. References are made to the elements identified in the drawings hereinafter with identical or similar reference symbols when referring to identical or similar elements.

FIG. 1 is a vertical cross sectional view of a PECVD apparatus 1 providing a schematic overview of the device. PECVD apparatus 1 comprises a body 2 shaped as a closed bottom cylinder, a showerhead 3 enclosing the top opening of body 2, and a stage 4 provided inside body 2. Stage 4, being earthed, serves as a lower electrode and also as a placement for supporting a wafer 5.

Showerhead 3 has a projection 6 that protrudes into body 2 so as to confront stage 4. Projection 6, when viewed from the exterior of body 2, defines a recess 7. The interior of recess 7 is partitioned by a partition element 8 disposed so as to close the top opening of recess 7. More specifically the interior of recess 7 is partitioned into a central gas inlet 9 and a peripheral gas inlet 10 by a cylindrical partition wall 8a extending from the underside of partition element 8.

Partition element 8 has in its central portion a gas delivery path 11 communicating with central gas inlet 9. Gas delivered from a later described gas source is delivered into central gas inlet 9 through gas delivery path 11. Gas supplied into central gas inlet 9 is introduced into body 2 through multiplicity of through holes (not shown) defined on a bottom wall 6a of projection 6. Above bottom wall 6a, a dispersion plate 12 in disc shape is disposed for gas dispersion.

At the left end as viewed in FIG. 1 of the outer periphery of partition element 8, a gas delivery path 13 is provided so as to be in communication with peripheral gas inlet 10. Gas delivered from a later described gas source flows into peripheral gas inlet 10 through gas delivery path 13. Gas delivered into peripheral gas inlet 10 is introduced into body 2 through the multiplicity of through holes defined on bottom wall 6a of projection 6. Above bottom wall 6a, a dispersion plate 14 in ring shape is disposed for gas dispersion.

Showerhead 3 functions as an upper electrode and is connected to one of the two terminals of a high-frequency power supply (RF power supply) 15. The remaining other terminal of high-frequency power supply 15 is earthed. On a portion of the inner peripheral wall of body 2 confronting the outer periphery of stage 4, a ring-shaped exhaust element 16 is disposed so as to rest upon a step provided on the inner peripheral wall of body 2. As can be seen in FIG. 2, exhaust element 16 has multiplicity of exhaust holes 16a defined on its inner peripheral surface which communicates with an annular communication path 16b running inside exhaust element 16.

On the inner peripheral wall of body 2, an exhaust port 17 is provided at a portion placed in abutment with the right end of exhaust element 16 as viewed in FIG. 1. Exhaust port 17 communicates with communication path 16b within exhaust element 16 through communication hole 16c. Exhaust port 17 has an exhaust pump (vacuum pump) not shown connected to it that forces gas inside body 2 to be discharged through exhaust element 16 and exhaust port 17.

The spacing between exhaust holes 16a defined on exhaust element 16 is adjusted depending upon their distance from exhaust port 17 (communication hole 16c) such that as FIG. 2 shows, the spacing becomes wider as exhaust holes 16a are located closer to exhaust port 17 and narrower as the exhaust holes 16a are located farther from exhaust port 17. Such arrangement allows gas inside body 2 to be exhausted evenly.

Dispersion plate 14 formed inside peripheral gas inlet 10 also has multiplicity of through holes (not shown) defined to it which are adjusted in spacing as was the case for exhaust holes 16a of exhaust element 16 such that spacing between the through holes become wider as the through holes are located closer to gas delivery path 13 and narrower as the through holes are located farther from gas delivery path 13. Such arrangement allows gas delivered from gas delivery path 13 to flow evenly into body 2.

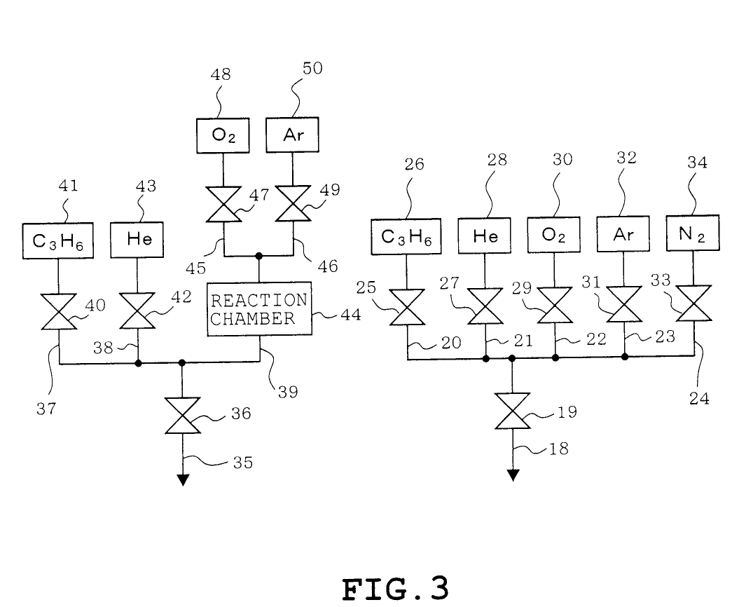

Next, with reference to FIG. 3, a description will be given on a gas delivery system that delivers various types of gas into central gas inlet 9 (gas delivery path 11) and peripheral gas inlet 10 (gas delivery path 13) within showerhead 3 of PECVD apparatus 1.

First, a description will be given on the gas delivery system responsible for supplying gas into gas delivery path 11 of central gas inlet 9. Gas delivery path 11 is connected at the lower end of a central gas conduit 18 as viewed in FIG. 3, which is provided with a central main valve 19. On the upper end of central gas conduit 18 as viewed in FIG. 3, five gas conduits 20 to 24 are connected in parallel. Gas conduit 20 is provided with a valve 25 and is connected to a gas source 260 of C₃H₆ gas. Likewise, gas conduit 21 is provided with valve 27 and is connected to gas source 28 of He gas; gas conduit 22 has valve 29 and is connected to gas source 30 of O₂ gas; gas conduit 23 has valve 31 and is connected to gas source 32 of Ar gas; and gas conduit 24 has valve 33 and is connected to gas source 34 of N₂ gas. Each of gas sources 26, 28, 30, 32, and 34 comprises an MFC (Mass Flow Controller) for controlling the supply of each type of gas, and a tank for storing each type of gas. In the above described configuration, by opening main valve 19 and opening/closing valves 25, 27, 29, 31, and 33 as required, one or 2 or more of C₃H₆ gas, He gas, O₂ gas, Ar gas, and N₂ gas can be supplied as required.

Next, a description will be given on the gas delivery system responsible for delivering gas into gas delivery path 13 of peripheral gas inlet 10. Gas delivery path 13 is connected to the lower end of a peripheral gas conduit 35 as viewed in FIG. 3, which is provided with a peripheral main valve 36. On the upper end of peripheral gas conduit 35 as viewed in FIG. 3, three gas conduits 37 to 39 are connected in parallel. Gas conduit 37 is provided with a valve 40 and is connected to a gas source 41 of C₃H₆ gas. Likewise, gas conduit 38 is provided with valve 42 and is connected to gas source 43 of He gas.

Gas conduit 39 is provided with a reaction chamber 44 and two gas conduits 45 and 46 connected in parallel. Reaction chamber 44 activates oxygen (O₂) supplied into it by microwave discharge. Gas conduit 45 has a valve 47 and is connected to gas source 48 of O₂ gas, and gas conduit 46 has a valve 49 and is connected to gas source 50 of Ar gas. Each of gas sources 41, 43, 48 and 50 comprises an MFC (Mass Flow Controller) for controlling the supply of each type of gas, and a tank for storing each type of gas. In the above described configuration, by opening main valve 36 and opening/closing valves 40, 42, 47, and 49 as required, one or 2 or more of C₃H₆ gas, He gas, O₂ gas, and Ar gas can be supplied as required.

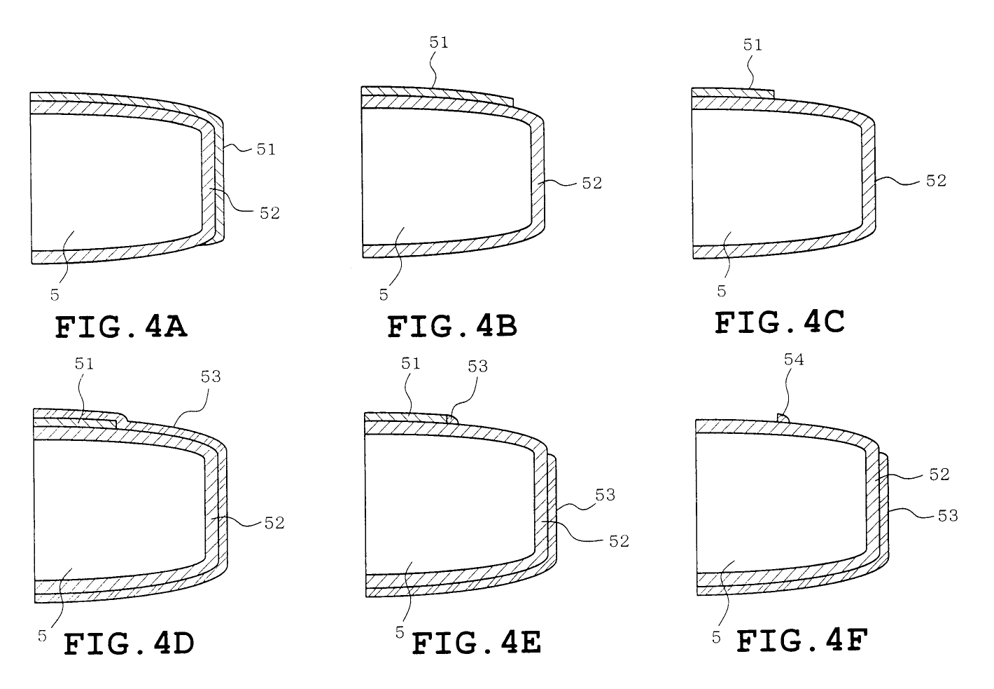

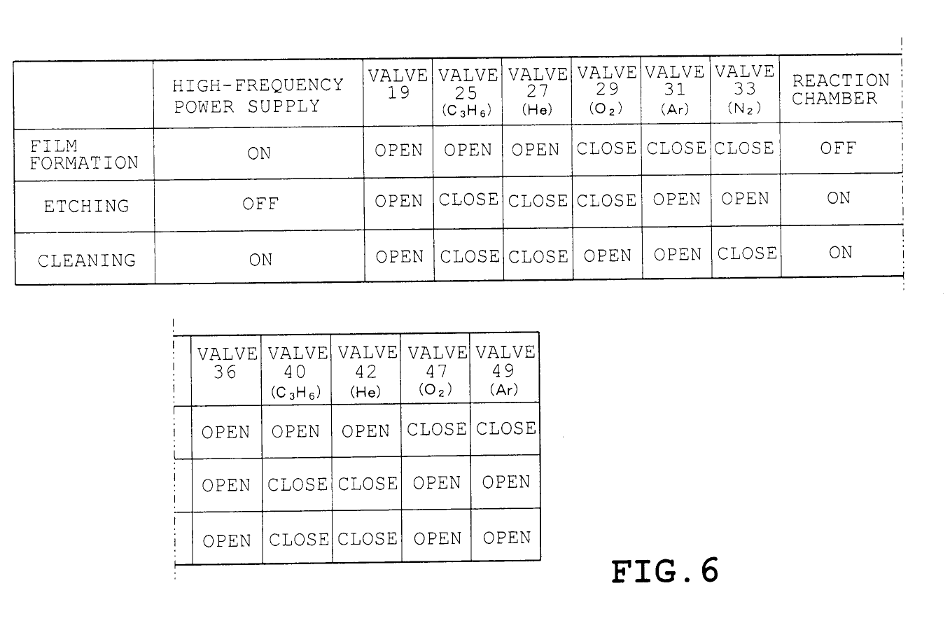

PECVD apparatus 1 being configured as described above forms carbon CVD film 51 on wafer 5. As indicated in the row labeled “film formation” in the table given in FIG. 6, high-frequency power supply 15 is turned on, main valve 19 opened, valves 25 and 27 opened, valves 29, 31, and 33 closed, reaction chamber 44 turned off, main valve 36 opened, valves 40 and 42 opened and valves 47 and 49 are closed. As a result of the above operation, C₃H₆ gas and He gas are introduced into body 2 via central gas inlet 9 and peripheral gas inlet 10 within showerhead 3 while high-frequency power supply 15 is turned on and discharge takes place between showerhead 3 and stage 4 to form carbon CVD film 51. FIG. 4A shows the resulting carbon CVD film 51. Of note is that carbon CVD film 51 is formed on a processing film 52 formed on wafer 5.

Next, after forming carbon CVD film 51 with PECVD apparatus 1 as described above, carbon CVD film 51 residing on the wafer bevel is etched away using PECVD apparatus 1. As indicated in the row labeled “etching” in the table given in FIG. 6, high-frequency power supply 15 is turned off, main valve 19 opened, valves 25, 27 and 29 closed, valves 31 and 33 opened, reaction chamber 44 turned on, main valve 36 opened, valves 40 and 42 closed and valves 47 and 49 are opened.

As a result of the above operation, Ar gas and N₂ gas (inert gas) are introduced into body 2 through central gas inlet 9 within showerhead 3 while Ar gas and O₂ gas activated by reaction chamber 44 are introduced into body 2 through peripheral gas inlet 10. As a result, activated oxygen (O₂) gas flows onto the outer peripheral portion of wafer 5 to allow carbon CVD film 51 residing on wafer 5 bevel to be etched away within body 2. Of note is that inert gas (Ar gas and N₂ gas) flown toward the central portion of wafer 5 keeps activated oxygen confined at wafer 5 bevel which is significantly advantageous in only etching away carbon CVD film 51 residing on wafer 5 bevel (refer to FIG. 4B). During etching, RF power of high-frequency power supply 15 is cut off from body 2 (that is, between showerhead 3 and stage 4) in order to prevent discharge between showerhead 3 and stage 4 from affecting carbon film 51 formed on the central portion of wafer 5.

Next, after forming an anti-reflection film (not shown) on the etched carbon CVD film 51, a predetermined processing is performed on carbon CVD film 51 (refer to FIG. 4C). Then, as shown in FIG. 4D, amorphous silicon film 53 serving as a spacer is formed on carbon CVD film 51. Thereafter, using carbon CVD film 51 as a stopper, amorphous silicon film 53 is etched by RIE (Reactive Ion Etching) as shown in FIG. 4E. Then, as shown in FIG. 4F, carbon CVD film 51 is removed by dry etching such as O₂ ashing. Removing carbon CVD film 51 serving as a core material by dry etching allows successful formation of spacer 54 without surface tension collapse which was a problem encountered in wet etching. Of note is that amorphous silicon film 53 residing on wafer 5 bevel is not removed by the dry etching.

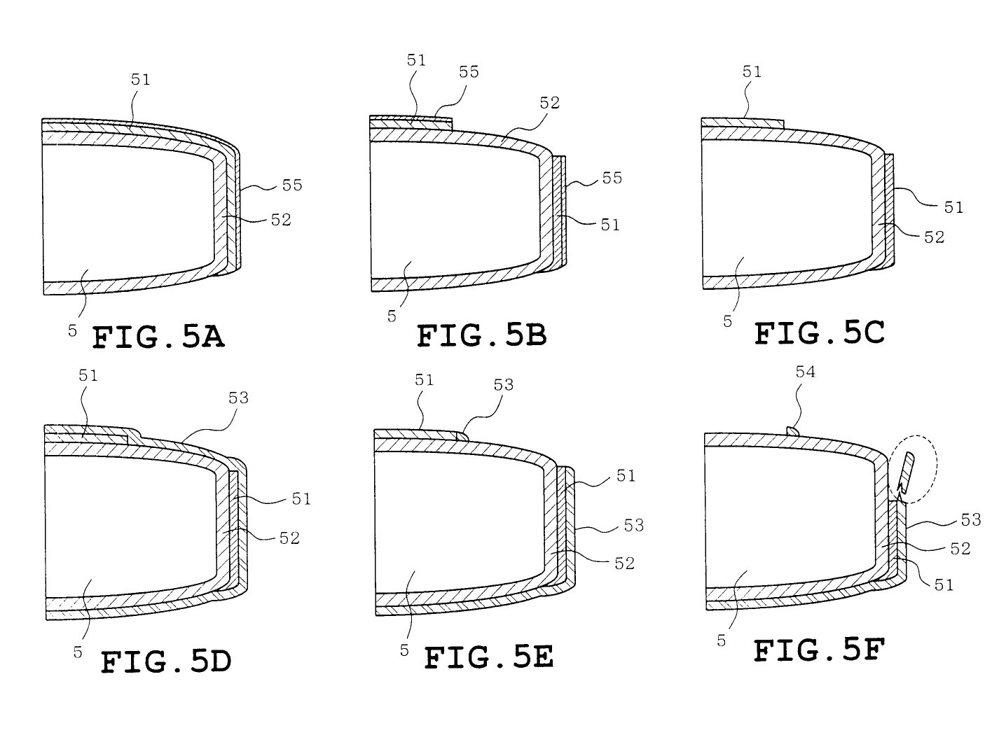

A comparative example (conventional approach) will now be described with reference to FIG. 5 which does not remove carbon CVD film 51 residing on wafer 5 bevel by etching. In the comparative example shown in FIG. 5A, anti-reflection film 55 is formed on carbon CVD film 51 after forming carbon CVD film 51 on processing film 52. Then, as shown in FIG. 5B, predetermined processing is performed on carbon CVD film 51. Next, as shown in FIG. 5C, anti-reflection film 55 is removed. Then, as shown in FIG. 5D, amorphous silicon film 53 serving as a spacer is formed on carbon CVD 51.

Thereafter, as shown in FIG. 5E, amorphous silicon film 53 is etched by RIE using carbon CVD film 51 as a stopper. Then, as shown in FIG. 5F, carbon CVD film 51 is removed to form spacer 54. The problem in this approach is delamination of carbon CVD film 51 and amorphous silicon film 53 residing on wafer 5 bevel.

In contrast, the present exemplary embodiment, as shown in FIG. 4B, removes carbon CVD film 51 residing on wafer 5 bevel by etching and thus, delamination of amorphous silicon film 53 from wafer 5 bevel can be prevented as can be seen in FIG. 4F.

Next, a description will be given on cleaning, in other words, empty heating of body 2 interior of PECVD apparatus 1. As indicated in the row labeled “cleaning” in the table given in FIG. 6, high-frequency power supply 15 is turned on, main valve 19 opened, valves 25, 27 and 33 closed, valves 29, 31 opened, reaction chamber 44 turned on, main valve 36 opened, valves 40 and 42 closed and valves 47 and 49 are opened.

As a result of the above operation, O₂ gas and Ar gas are introduced into body 2 through central gas inlet 9 within showerhead 3 while introducing Ar gas and O₂ gas activated by reaction chamber 44 into body 2 through peripheral gas inlet 10 within showerhead 3. Then, high-frequency power supply 15 is turned on and discharge takes place between showerhead 3 and stage 4 to activate O₂ gas introduced into body 2 and clean the interior of body 2 with the activated O₂ gas.

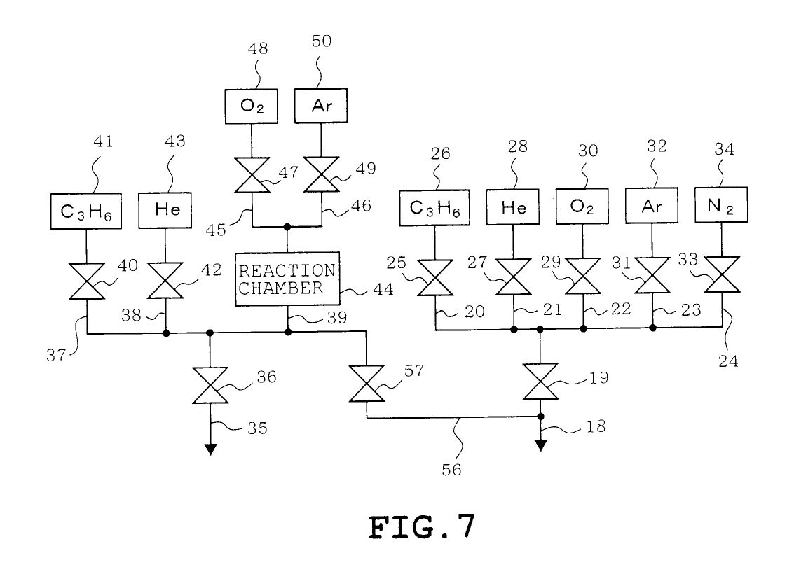

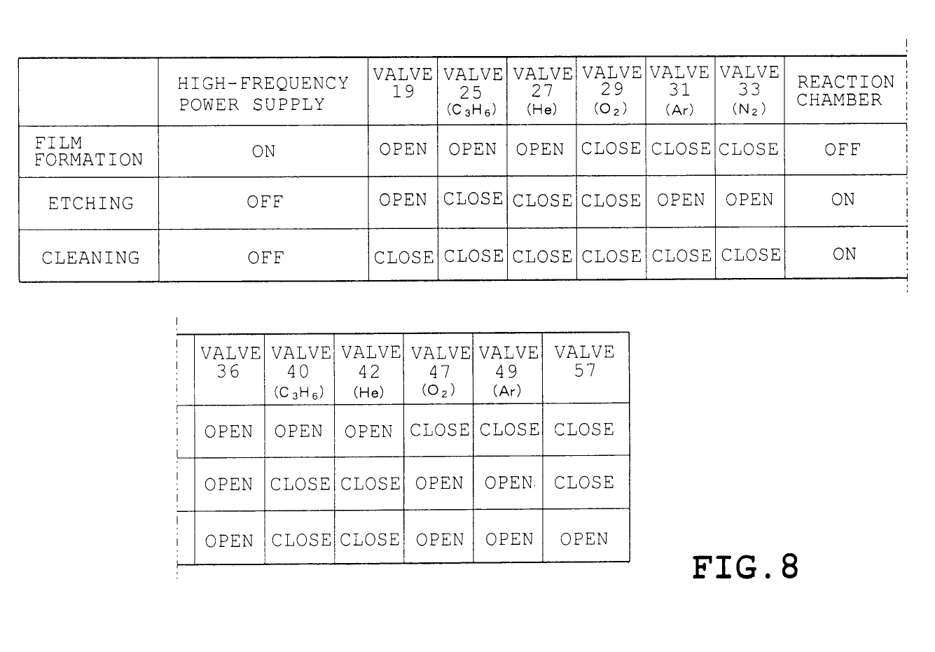

FIGS. 7 and 8 depict a second exemplary embodiment of the present disclosure. Portions that are identical to the first exemplary embodiment are identified with identical reference symbols. In the second exemplary embodiment, as can be seen in FIG. 7, the portion of central gas conduit 18 connecting to gas delivery path 11 and the portion of gas conduit 39 connecting to peripheral gas conduit 35 are connected by a connecting gas conduit 56 which is provided with valve 57.

When forming carbon CVD film 51 on wafer 5 using PECVD apparatus 1 of the second exemplary embodiment, valve 57 of connecting gas conduit 56 is closed as indicated in the row labeled “film formation” in the table given in FIG. 8, and other on/off, open/close operations of valves etc., remain the same as the first exemplary embodiment (refer to FIG. 6).

Etching of carbon CVD film 51 residing on wafer 5 bevel performed using PECVD apparatus 1 after formation of carbon CVD film 51 in the above described manner is carried out by closing valve 57 of connecting gas conduit 56 as indicated in the row labeled “etching” in the table given in FIG. 8, and other on/off, open/close operations of valves etc., remain the same as the first exemplary embodiment (refer to FIG. 6).

Cleaning of the interior of body 2 using PECVD apparatus 1 is carried out by opening valve 57 of connecting gas conduit 56 as indicated in the row labeled “cleaning” in the table given in FIG. 8. This time, however, other on/off, open/close operations of valves etc., are different from the first exemplary embodiment. More specifically, as indicated in the row labeled “cleaning” in the table given in FIG. 8, high-frequency power supply 15 is turned off, main valve 19 closed, valves 25, 27, 29, 31 and 33 closed, reaction chamber 44 turned on, main valve 36 opened, valves 40 and 42 closed and valves 47,49, and 57 are opened.

As a result of the above operation, Ar gas and O₂ gas activated by reaction chamber 44 are introduced into body 2 through central gas inlet 9 as well as through peripheral gas inlet 10 within showerhead 3. As a result, the interior of body 2 can be cleaned with activated O₂ without discharge taking place between showerhead 3 and stage 4 which is burdensome to body 2.

Other features not mentioned above remain the same from the first exemplary embodiment. Thus, the second exemplary embodiment obtains the same effects as the first exemplary embodiment.

The present disclosure is not limited to the above described exemplary embodiments but may be modified or expanded as follows.

Exhaust holes 16a formed on the inner peripheral surface of exhaust element 16 (refer to FIG. 2) may be provided on other surfaces of exhaust element 16 such as on the upper surface of exhaust element 16 or on both the inner peripheral surface and the upper surface of exhaust element 16.

Further, a single gas delivery path 13 in communication with peripheral gas inlet 10 is provided at the left end of the outer periphery of partition element 8 as viewed in FIG. 1 in the above exemplary embodiments. Alternatively, two or more gas delivery paths 13 in communication with peripheral gas inlet 10 may be provided at the outer periphery of partition element 8, and gas may be delivered into peripheral gas inlet 10 from the two or more gas delivery paths 13.

Ar gas and N₂ gas are employed as inert gases directed to the central portion of wafer 5 to facilitate removing of carbon CVD film 51 residing on wafer 5 bevel in the present exemplary embodiment. Alternatively, at least one of Ar gas and N₂ gas as well as other combinations of gases may be employed and delivered toward the central portion of wafer 5.

The foregoing description and drawings are merely illustrative of the principles of the present disclosure and are not to be construed in a limited sense. Various changes and modifications will become apparent to those of ordinary skill in the art. All such changes and modifications are seen to fall within the scope of the disclosure as defined by the appended claims.

What is claimed is:

1. A semiconductor manufacturing apparatus that forms a carbon film on a wafer by plasma enhanced chemical vapor deposition, comprising:
a body having a top opening;
a stage provided within the body for placement of the wafer;
a showerhead that encloses the top opening and that introduces a deposition gas or an etch gas; and
a gas delivery system including a central gas inlet that introduces gas toward a central portion of the wafer from a central portion of the showerhead, and a peripheral gas inlet that introduces gas toward a bevel of the wafer from an outer peripheral portion of the showerhead,
wherein the gas delivery system, after activating the etch gas outside the body, delivers the activated etch gas toward the bevel of the wafer to selectively remove a portion of the carbon film formed on the bevel of the wafer.

2. The apparatus according to claim 1, wherein the gas delivery system further delivers an inert gas toward the central portion of the wafer from the central gas inlet when delivering the etch gas activated outside the body toward the bevel of the wafer from the peripheral gas inlet.

3. The apparatus according to claim 1, wherein the gas delivery system further allows delivery of the etch gas into the body from the peripheral gas inlet and the central gas inlet for cleaning an interior of the body.

4. The apparatus according to claim 1, wherein the showerhead includes a protrusion having a first side protruding into the body so as to confront the stage and a second side defining a recess opening up toward an exterior of the body, a partition element that encloses an upper opening of the recess, and a cylindrical partition wall that extends from an underside of the partition element to partition the recess into the central gas inlet and the peripheral gas inlet.

5. The apparatus according to claim 4, wherein the showerhead further comprises a disc-shaped dispersion plate disposed within the central gas inlet that promotes gas dispersion and a ring-shaped dispersion plate disposed within the peripheral gas inlet that promotes gas dispersion.

6. The apparatus according to claim 1, wherein the showerhead serves as an upper electrode and is connected to a first terminal of a high-frequency power supply having a second terminal that is earthed, and wherein the stage that is earthed serves as a lower electrode.

7. The apparatus according to claim 1, further comprising an exhaust element in ring shape disposed at a portion of an inner periphery of the body that confronts an outer periphery of the stage.

8. The apparatus according to claim 7, wherein the exhaust element includes a multiplicity of exhaust holes defined on a surface thereof and an annular communication path defined in the exhaust element in communication with the multiplicity of exhaust holes, and wherein the body includes an exhaust port provided at a portion of a peripheral wall of the body placed in abutment with the exhaust element so as to be in communication with the communication path of the exhaust element, the exhaust port being connected to an exhaust pump.

9. The apparatus according to claim 8, wherein the multiplicity of exhaust holes located relatively closer to the exhaust port are spaced farther apart from each other whereas the multiplicity of exhaust holes located relatively farther from the exhaust port are spaced closer together from each other.

10. The apparatus according to claim 1, further comprising a gas conduit that connects the peripheral gas inlet with a gas source of the etch gas, the gas conduit having a reaction chamber provided at an intermediate portion thereof.

11. The apparatus according to claim 10, wherein the reaction chamber activates the etch gas delivered thereto by microwave discharge.

12. The apparatus according to claim 1, wherein the etch gas comprises O₂ gas.

13. The apparatus according to claim 2, wherein the inert gas comprises at least one of N₂ gas and Ar gas.

14. A method of manufacturing a semiconductor device in which a carbon film formation with plasma enhanced chemical vapor deposition is performed, comprising:
forming the carbon film on a wafer by introducing a deposition gas from a central gas inlet positioned at a central portion of a showerhead and a peripheral gas inlet positioned at a peripheral portion of the showerhead, the showerhead enclosing an upper opening of a body of a plasma enhanced chemical vapor deposition apparatus, and
etching away the carbon film formed on a bevel of the wafer by delivering a first etch gas activated outside the body toward the bevel of the wafer from the peripheral gas inlet.

15. The method according to claim 14, wherein an inert gas is delivered toward a central portion of the wafer from the central gas inlet when etching away the carbon film formed on the bevel of the wafer.

16. The method according to claim 15, wherein the inert gas comprises at least one of N₂ gas and Ar gas.

17. The method according to claim 14, wherein the deposition gas comprises C₃H₆ gas and He gas and the first etch gas comprises O₂ gas.

18. The method according to claim 14, wherein the carbon film formed on the bevel of the wafer is etched away without generating discharge between the showerhead and a stage provided for placement of the wafer.

19. The method according to claim 14, further comprising cleaning an interior of the body with an activated etch gas including:
introducing a second etch gas into the body from the central gas inlet;
introducing a third etch gas activated outside the body into the body from the peripheral gas inlet; and
generating discharge between the showerhead and a stage provided for wafer placement by turning on a high-frequency power supply to activate the second etch gas introduced into the body.

20. The method according to claim 14, further comprising cleaning an interior of the body with an activated etch gas including:
introducing the activated etch gas activated outside the body into the body from the central gas inlet;
introducing the activated etch gas activated outside the body into the body from the peripheral gas inlet; and
preventing discharge between the showerhead and a stage provided for wafer placement.
